(19) United States
(12) Patent Application Publication
(10) Pub. No.: US 2013/0342984 A1
(43) Pub. Date: Dec. 26, 2013

(54) ELECTRONIC MODULE WITH CONNECTOR AND ELECTRONIC DEVICE USING SAME

(71) Applicant: HON HAI PRECISION INDUSTRY CO., LTD., New Taipei (TW)

(72) Inventor: ZHENG-HENG SUN, New Taipei (TW)

(21) Appl. No.: 13/923,398

(22) Filed: Jun. 21, 2013

(30) Foreign Application Priority Data
Jun. 25, 2012 (CN) 2012102099737

(51) Int. Cl. H05K 5/02; G06F 1/18; H05K 7/20

(52) U.S. Cl. CPC H05K 5/02; H05K 7/20127; G06F 1/184
USPC 361/679.02; 361/728; 361/690

(57) ABSTRACT

An electronic module includes a shell, a circuit board, and a connector. The shell defines a receiving slot. The circuit board includes a main body and an extension body connected to the main body. The main body of the circuit board is received in the shell, and the extension body of the circuit board extends out of the shell via the receiving slot.

The connector is fixed in place by being attached to the extension body of the circuit board.

### BACKGROUND

1. Technical Field

The present disclosure generally relates to an electronic module and an electronic device using the same, and especially relates to an electronic module with a connector.

2. Description of Related Art

Most electronic devices use power supply units to provide power to internal components of the electronic devices. For example, a typical server 1, as shown in FIG. 1, includes a power supply unit 12, a motherboard 16, and a connection cable 13. The power supply unit 12 includes a shell 120 to receive internal functional components of the power supply unit 12, and a power cable 121 extending out of the shell 120. The power cable 121 employs a connector 122 at a distal end thereof. The motherboard 16 employs a connector 166 as a power interface. The connection cable 13 includes a first connector 132 and a second connector 136 at opposite distal ends thereof. The first connector 132 matches with the connector 122 of the power cable 121, and the second connector 136 matches with the connector 166 of the mother board 16. The first connector 132 is connected to the connector 122 of the power supply unit 12, and the second connector 136 is connected to the connector 166 of the motherboard 16. Therefore, the power supply unit 12 can provide power to the motherboard 16 via the connection cable 13.

However, because such a connection structure formed by the connector 122 and the connector 132 occupies a deal of space, and the connection structure may move in union with the power cable 12 and the connection cable 13, the connection structure may impact or contact other internal components of the server 1, which makes the server 1 less reliable.

What is needed, therefore, is a means which can overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of a typical electronic device of prior art.

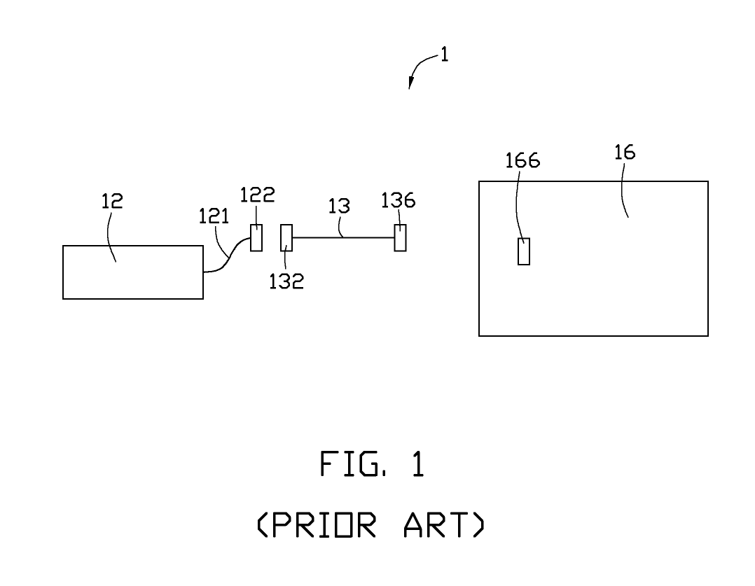

FIG. 2 is an isometric view of an electronic device according to an exemplary embodiment of the present disclosure, the electronic device including an electronic module, a connection cable, and an electronic system.

FIG. 3 is an enlarged, exploded, isometric view of the electronic module of the electronic device of FIG. 2.

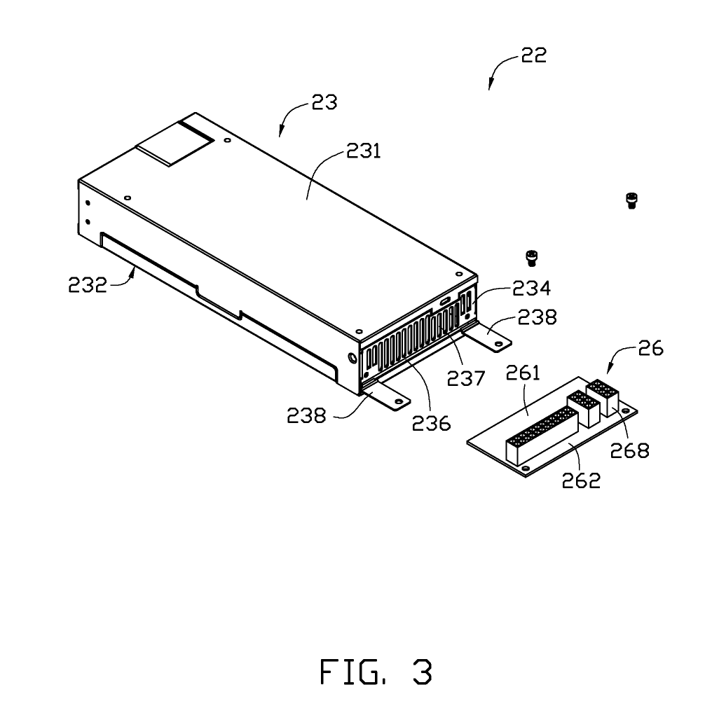

FIG. 4 is similar to FIG. 1, but shows the electronic module being applied in different electronic systems.

### DETAILED DESCRIPTION

Reference will be made to the drawings to describe various embodiments.

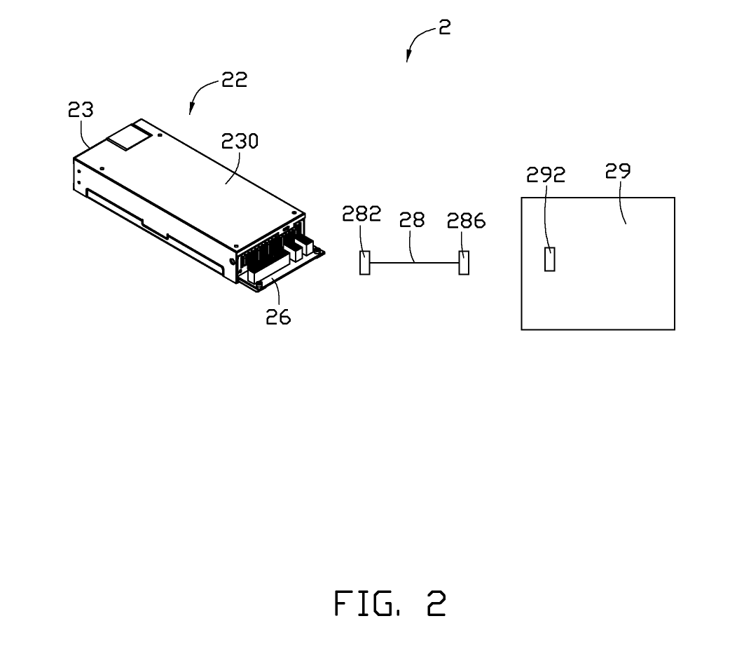

FIG. 2 shows one embodiment of an electronic device 2. The electronic device 2 includes an electronic module 22, a connection cable 28, and an electronic system 29. The connection cable 28 transmits electronic signals and power between the electronic module 22 and the electronic system 29. For example, the electronic device 2 may be a server, the electronic module 22 may be a power supply unit, and the electronic system 29 may be a motherboard of the server, and the power supply unit provides power to the motherboard via the connection cable 28.

The electronic module 22 includes a shell 23 and a circuit board 26. The shell 23 defines an accommodating space 230 to receive internal components of the electronic module 22 and a receiving slot 236. The receiving slot 236 provides intercommunication between the accommodating space 230 and the outside of the shell 23.

The circuit board 26 includes a main body 261 and an extension body 262 connecting to the main body 261. The main body 261 of the circuit board 26 is received in the accommodating space 230 of the shell 23. The extension body 262 of the circuit board 26 passes through the receiving slot 236 and extends out of the shell 23. At least one connector 268 attaches to the extension body 262 of the circuit board 26 and locates outside of the shell 23. The at least one connector 268 provides a channel for electronic signals to be transmitted between the at least one connector 268 and the circuit board 26. In this embodiment, the at least one connector 268 includes three connectors, and a type of each connector is different, so as to be compatible with various types of connectors.

The shell 23 includes a top plate 231, a bottom plate 232, and a plurality of sidewalls 234. The top plate 231, the bottom plate 232, and the sidewalls 234 cooperate to form the accommodating space 230 to receive internal components of the electronic module 22. In this embodiment, the shell 23 is a hexahedron and includes four sidewalls 234. The receiving slot 236 is defined in a bottom portion of one of the sidewalls 234 adjacent to the bottom plate 232, and the one of the sidewalls 234 further defines a plurality of ventilation holes 237. Two fixing plates 238 are arranged opposite to each other and extend from a same edge of the bottom plate 232 adjacent to the receiving slot 236. The fixing plates 238 are coplanar with the bottom plate 232. The extension body 262 of the circuit board 26 is fixed to the fixing plates 238 via screws, for example.

The electronic system 29 includes a connector 292 which is employed as a power interface. The connection cable 28 includes a first connector 282 and a second connector 286 at opposite ends of the connection cable 28. The first connector 282 matches with a connector 268 of the electronic module 22, and the second connector 286 matches with the connector 292 of the electronic system 29. The first connector 282 connects to the connector 268 of the electronic module 22, and the second connector 268 connects to the connector 292 of the electronic system 29, thus transmitting electronic signals between the electronic module 22 and the electronic system 29.

With the above-described configuration, because the connectors 268 are attached to the extension body 262 of the circuit board 26, the connectors 268 are fixed in place. Therefore, the connection structure formed by the connectors 268 and the connector 282 is secure, and the connection structure cannot impact or push against the internal components of the electronic device 2, thus providing higher reliability. Furthermore, the electronic module 22 includes different types of connectors, so a match for any certain type of connector can be found.

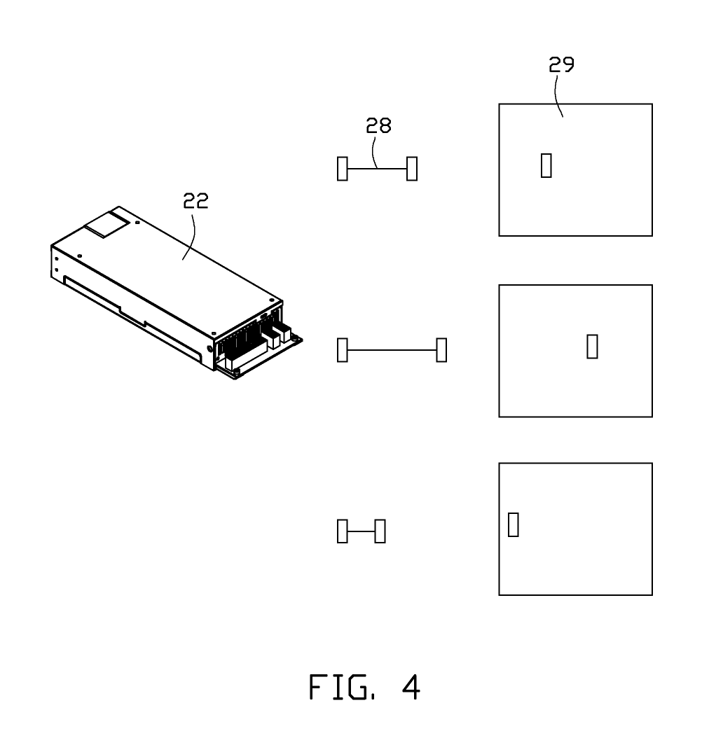

The electronic module 22 also has a wide versatility; it can be used for example in different types of electronic systems 29 (see FIG. 4), and the locations of the connectors 292 of the electronic systems 29 may be at different areas in the different types of the electronic systems 29. When electronic signals are to be transmitted between the electronic module 22 and a certain type of the different types of electronic systems 29, a connection cable 28 with suitable length and matching connectors can be selected, to electrically interconnect them.

It is believed that the present embodiments and their advantages will be understood from the foregoing description, and it will be apparent that various changes may be made thereto without departing from the spirit and scope of the description or sacrificing all of their material advantages, the examples hereinbefore described merely being exemplary embodiments.

What is claimed is:

1. An electronic module, comprising:
a shell defining an accommodating space to receive internal components of the electronic module and a receiving slot intercommunicating with the accommodating space and the outside of the shell;
a circuit board comprising a main body received in the accommodating space and an extension body connected to the main body, the extension body extending out of the accommodating space via the receiving slot; and
a connector attached to the extension body of the circuit board and configured to provide a transmitting channel allowing desired electronic signals to be transmitted between the connector and the circuit board.

2. The electronic module of claim 1, wherein the electronic module is a power supply unit.

3. The electronic module of claim 1, wherein the shell comprises a bottom plate, a top plate, and a plurality of sidewalls; the bottom plate, the top plate and the sidewalls cooperate to define the accommodating space.

4. The electronic module of claim 3, wherein the receiving slot is defined in a bottom portion of one of the sidewalls adjacent to the bottom plate.

5. The electronic module of claim 4, wherein two fixing plates are arranged opposite to each other and located at a same edge of the bottom plate adjacent to the receiving slot, and the extension body of the circuit board is fixed to the fixing plates.

6. The electronic module of claim 4, wherein the one of the sidewalls further defines a plurality of ventilation holes.

7. The electronic module of claim 1, wherein another two connectors are located on the extension body, and a type of each connector located on the extension body is different.

8. An electronic device, comprising:
an electronic module comprising a shell, a circuit board, and a connector, the shell defining an accommodating space to receive internal components of the electronic module and a receiving slot intercommunicating with the accommodating space and the outside of the shell, the circuit board comprising a main body received in the accommodating space and an extension body connected to the main body, the extension body extending out of the accommodating space via the receiving slot, the connector attached to the extension body of the circuit board and configured to provide a transmitting channel allowing desired electronic signals to be transmitted between the connector and the circuit board;
an electronic system comprising a connector; and
a connection cable comprising a first connector matching with the connector of the electronic module and a second connector matching with the connector of the electronic system, and the electronic module transmitting electronic signals to the electronic system via the connection cable.

9. The electronic device of claim 8, wherein the electronic device is a server, the electronic module is a power supply unit, and the electronic system is a motherboard of the server.

10. The electronic device of claim 8, wherein the shell comprises a bottom plate, a top plate, and a plurality of sidewalls; the bottom plate, the top plate and the sidewalls cooperate to define the accommodating space.

11. The electronic device of claim 10, wherein the receiving slot is defined in a bottom portion of one of the sidewalls adjacent to the bottom plate.

12. The electronic device of claim 11, wherein two fixing plates are arranged opposite to each other and located at a same edge of the bottom plate adjacent to the receiving slot, and the extension body of the circuit board is fixed to the fixing plates.

13. The electronic device of claim 11, wherein the one of the sidewalls further defines a plurality of ventilation holes.

14. The electronic device of claim 1, wherein another two connectors are located on the extension body, and a type of each connector located on the extension body is different.
